(19) United States
(12) Patent Application Publication
(10) Pub. No.: US 2014/0211414 A1
(43) Pub. Date: Jul. 31, 2014

(54) HEAT DISSIPATION DEVICE AND ELECTRONIC DEVICE USING SAME

(71) Applicants: HON HAI PRECISION INDUSTRY CO., LTD., New Taipei (TW); HONG FU JIN PRECISION INDUSTRY (ShenZhen) CO., LTD., ShenZhen (CN)

(72) Inventor: KANG WU, Shenzhen (CN)

(73) Assignees: HONG FU JIN PRECISION INDUSTRY (ShenZhen) CO., LTD., ShenZhen (CN); HON HAI PRECISION INDUSTRY CO., LTD., New Taipei (TW)

(21) Appl. No.: 14/037,408

(22) Filed: Sep. 26, 2013

(30) Foreign Application Priority Data
Jan. 31, 2013 (CN) 201310037962X

(51) Int. Cl. H05K 7/20; F04D 27/00; G06F 1/20

(52) U.S. Cl. CPC H05K 7/20172; G06F 1/20; F04D 27/001
USPC 361/679.48; 361/695; 416/61

(57) ABSTRACT

A heat dissipation device is for dissipating heat generated from an electronic device, and includes at least one fan and a control device. The control device detects a rotational speed of each of the at least one fan, determines whether the rotational speed of the at least one fan is less than a predetermined value, and determines whether an notification signal is output based on the determination.

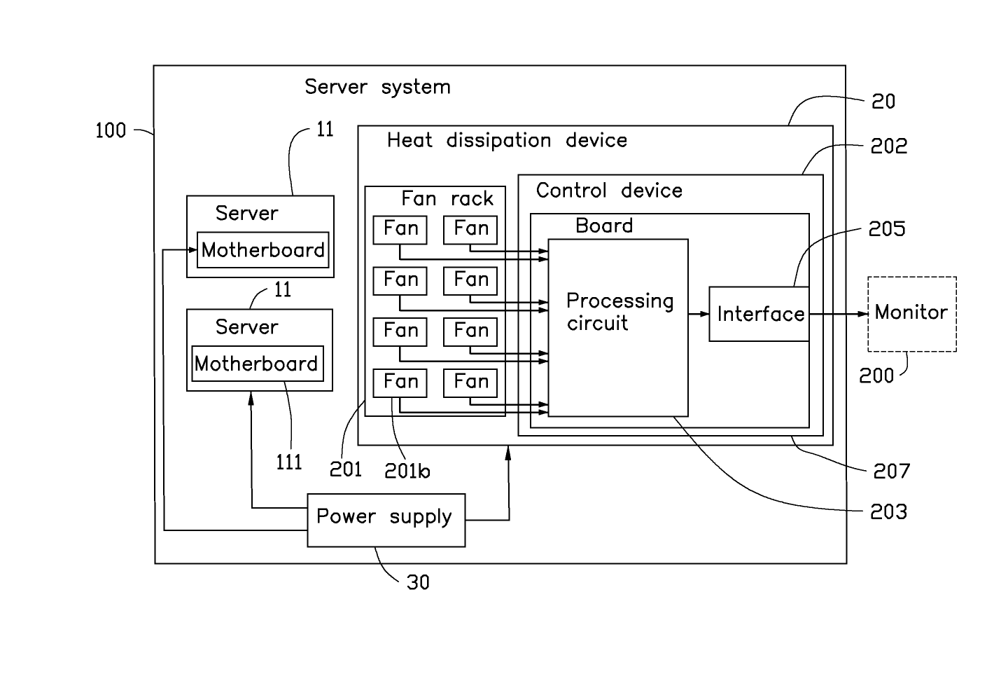

### BACKGROUND

1. Technical Field

The present disclosure relates to heat dissipation technology for electronic apparatuses, and more particularly, to a heat dissipation device and an electronic device using the heat dissipation device.

2. Description of Related Art

Electronic devices, such as server systems, usually employ fans to dissipate heat generated by multiple heat-generating electronic components in the electronic devices. However, when capability of a fan degrades, the fan may run slow, resulting in bad heat dissipation. Because operators may not be able to find fans whose capability degrade in time, reliability of the electronic devices employed the fans degrade.

What is needed, therefore, is an item which can overcome the described limitations.

### BRIEF DESCRIPTION OF THE DRAWINGS

The FIGURE is a schematic structural diagram illustrating one embodiment of a server system according to the present disclosure.

### DETAILED DESCRIPTION

Reference will now be made to the drawings to describe specific exemplary embodiments of the present disclosure.

The present disclosure relates to a heat dissipation device 20 employed in a server system 100, but the heat dissipation device 20 may be employed in other appropriate electronic devices.

The FIGURE is a schematic structural diagram illustrating one embodiment of the server system 100. The server system 100 includes at least one server 11, a heat dissipation device 20, and a power supply 30. In the present embodiment, number of the at least one server 11 is two. However, in alternative embodiments, the number of the at least one server 11 may be one, three, or more. The two servers 11 process data and execute corresponding functions. The heat dissipation device 20 dissipates heat generated by the two servers 11. The power supply 30 is connected to the two servers 11 and the heat dissipation device 20, and supplies electrical energy to the two servers 11 and the heat dissipation device 20.

Each of the two servers 11 includes at least one motherboard 111. The at least one motherboard 111 is a central component of the server 11, and is configured to process data. In the present embodiment, each of the two servers 11 includes a motherboard 111.

In alternative embodiments, each of the two servers 11 may include two or more motherboards 111.

The heat dissipation device 20 includes a fan rack 201, at least one fan 201b positioned on the fan rack 201, and a control device 202. In the present embodiment, the number of the at least one fan 201b is eight. In alternative embodiments, the number of the at least one fan 201b may be one, two, or more. The eight fans 201b dissipate heat generated by the two servers 11.

The control device 202 includes a processing circuit 203, an interface 205, and a board 207. The processing circuit 203 and the interface 205 are positioned on the board 207. The processing circuit 203 is connected to the eight fans 201b and the interface 205.

The interface 205 is configured to connect to a monitor 200. The interface 205 may be RJ45 interface, for example.

The processing circuit 203 detects a rotational speed of each of the eight fans 201b and determines whether the rotational speed of the eight fans 201b is less than a predetermined value. When the processing circuit 203 determines that the rotational speed of a fan 201b is less than the predetermined value, the processing circuit 203 outputs a notification signal to the monitor 200 via the interface 205, to notify a user that the rotational speed of which fan 201b is less than the predetermined value. When the processing circuit 203 determines that the rotational speed of the eight fans 201b is not less than the predetermined value, the processing circuit 203 does not output the notification signal. The predetermined value may be equal to rotational speed of a fan 201b when capability of the fan 201b is in a normal state. For different servers 11, the predetermined value may be different.

Since the control device 202 determines whether the rotational speed of the fans 201b is less than the predetermined value and outputs the notification signal to the monitor 200, the user can learn that the rotational speed of which fan 201b is less than the predetermined value according to information displayed on the monitor 200, and repair or replace the unqualified fan 201b in time. Accordingly, reliability of the heat dissipation device 20 and the server system 100 employing the heat dissipation device 20 improves.

It is believed that the present embodiments and their advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A heat dissipation device, comprising:
at least one fan; and
a control device connected to the at least one fan, the control device detecting a rotational speed of each of the at least one fan, determining whether the rotational speed of the at least one fan is less than a predetermined value, and outputting a notification signal based on the determination.

2. The heat dissipation device of claim 1, wherein the notification signal is representative of the rotational speed of which fan is less than the predetermined value.

3. The heat dissipation device of claim 2, wherein when the control device determines that the rotational speed of a fan is less than the predetermined value, the control device outputs the notification signal; when the control device determines that the rotational speed of the at least fan is not less than the predetermined value, the control device does not output the notification signal.

4. The heat dissipation device of claim 3, wherein the control device comprises a processing circuit connected to the at least one fan, the processing circuit detects rotational speed of each of the at least one fan, determines whether the rotational speed of the at least one fan is less than a predetermined value, and determines whether the notification signal is output based on the determination.

5. The heat dissipation device of claim 4, wherein the control device further comprises an interface connected to the processing circuit, and the processing circuit outputs the notification signal via the interface.

6. The heat dissipation device of claim 5, wherein the control device further comprises a board, the interface and the processing circuit are positioned on the board.

7. A server system, comprising:
at least one server; and
a heat dissipation device dissipating heat generated by the at least one server, comprising:
at least one fan; and
a control device connected to the at least one fan, detecting rotational speed of each of the at least one fan, determining whether the rotational speed of the at least one fan is less than a predetermined value, and determining whether an notification signal is output based on the determination.

8. The server system of claim 7, wherein the notification signal is representative of the rotational speed of which fan is less than the predetermined value.

9. The server system of claim 8, wherein when the control device determines that the rotational speed of a fan is less than the predetermined value, the control device outputs the notification signal; when the control device determines that the rotational speed of the at least fan is not less than the predetermined value, the control device does not output the notification signal.

10. The server system of claim 9, wherein the control device comprises a processing circuit connected to the at least one fan, the processing circuit detects rotational speed of each of the at least one fan, determines whether the rotational speed of the at least one fan is less than a predetermined value, and determines whether the notification signal is output based on the determination.

11. The server system of claim 10, wherein the control device further comprises an interface connected to the processing circuit, the processing circuit outputs the notification signal via the interface.

12. The server system of claim 11, wherein the control device further comprises a board, the interface and the processing circuit are positioned on the board.

13. The server system of claim 12, further comprising a power supply, wherein the power supply is connected to the at least one server and the heat dissipation device, and supplies electrical energy to the at least one server and the heat dissipation device.

14. An electronic device, comprising:
heat-generating electronic components; and
a heat dissipation device dissipating heat generated by the heat-generating electronic components, comprising:
at least one fan; and
a control device connected to the at least one fan, detecting rotational speed of each of the at least one fan, determining whether the rotational speed of the at least one fan is less than a predetermined value, and determining whether an notification signal is output based on the determination.

15. The electronic device of claim 14, wherein the notification signal is representative of the rotational speed of which fan is less than the predetermined value.

16. The electronic device of claim 15, wherein when the control device determines that the rotational speed of a fan is less than the predetermined value, the control device outputs the notification signal; when the control device determines that the rotational speed of the at least fan is not less than the predetermined value, the control device does not output the notification signal.

17. The electronic device of claim 16, wherein the control device comprises a processing circuit connected to the at least one fan, the processing circuit detects rotational speed of each of the at least one fan, determines whether the rotational speed of the at least one fan is less than a predetermined value, and determines whether the notification signal is output based on the determination.

18. The electronic device of claim 17, wherein the control device further comprises an interface connected to the processing circuit, the processing circuit outputs the notification signal via the interface.

19. The electronic device of claim 18, wherein the control device further comprises a board, the interface and the processing circuit are positioned on the board.

20. The electronic device of claim 19, further comprising a power supply, wherein the power supply is connected to the at least one server and the heat dissipation device, and supplies electrical energy to the at least one server and the heat dissipation device.
